(19) United States
(12) Patent Application Publication
(10) Pub. No.: US 2010/0014682 A1
(43) Pub. Date: Jan. 21, 2010

(54) AUDIO PROCESSING APPARATUS AND METHOD THEREOF TO PROVIDE HEARING PROTECTION

(75) Inventor: Ki-hoon Shin, Seonggnam-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/353,306

(22) Filed: Jan. 14, 2009

(30) Foreign Application Priority Data
Jul. 16, 2008 (KR) 2008-69310

(51) Int. Cl. H03G 3/20

(52) U.S. Cl. 381/57

(57) ABSTRACT

An audio processing apparatus, and method thereof, to provide hearing protection during audio playback in a portable multimedia device. The method includes sampling audio signals and ambient noise signals for a predetermined time frame, calculating means of audio energy and noise level accumulated for the predetermined time frame, from the sampled audio signals and the sampled ambient noise signals, and performing a noise cancellation process or a hearing protection process each time the extracted audio energy and the extracted noise level exceed or are equal to predetermined critical levels.

### CROSS-REFERENCE TO RELATED APPLICATIONS

This application claims the benefit of U.S. Provisional Application No. 60/021,925, filed on Jan. 18, 2008, in the U.S. Patent and Trademark Office, and the benefit of Korean Patent Application No. 10-2008-0069310, filed on Jul. 16, 2008, in the Korean Intellectual Property Office, the disclosures of which are incorporated herein in their entirety by reference.

### BACKGROUND OF THE INVENTION

1. Field of the Invention

The present general inventive concept relates to a portable multimedia device such as MP3 players, cellular phones, portable game consoles, etc., and more particularly, to an audio processing apparatus and method thereof to provide hearing protection during audio playback.

2. Description of the Related Art

Recent research indicates that one out of ten people experiences hearing loss, which affects one's capability of normally recognizing voice and/or music.

Rapid industrialization has been enhancing the lifestyles of people; however, it has been also increasing noises and environmental pollutions that cause hearing loss.

Nevertheless, most people do not recognize their hearing loss and are exposed to the causes of hearing loss without any protection.

Recently, portable audio playback devices, such as compact disc players (CDP) and motion picture experts group audio layer-3 (MP3) players, can be used without being limited by location and time, and are popular.

Most users carry such portable audio playback devices with them and listen to music with earphones.

In the street or subway, there are many people who listen to music at too high of a volume to block out external noises, and over time, this significantly affects their hearing and causes hearing loss.

### SUMMARY OF THE INVENTION

The present general inventive concept provides an audio processing apparatus and method thereof to provide hearing protection in a portable multimedia device.

Additional aspects and utilities of the present general inventive concept will be set forth in part in the description which follows and, in part, will be obvious from the description, or may be learned by practice of the general inventive concept.

Embodiments of the present general inventive concept provide an audio processing method that includes: sampling audio signals and ambient noise signals for a predetermined time frame; calculating means of audio energy and noise level accumulated for the predetermined time frame, from the sampled audio signals and the sampled ambient noise signals; and performing a noise cancellation process or a hearing protection process each time the extracted audio energy and the extracted noise level exceed predetermined critical levels.

Embodiments of the present general inventive concept also provide an audio processing device including: a signal processor to sample audio signals and ambient noise signals for a predetermined time frame, to calculate audio energy and noise level accumulated for the predetermined time frame, and to perform noise removal when the mean noise level exceeds a predetermined critical level; a hearing protection unit to calculate warning parameters when the mean audio energy exceeds a predetermined critical level and to adjust a current audio volume level to a preset recommended audio volume level if a hearing protection mode is enabled when the mean audio energy exceeds the predetermined critical level; and a display unit to display warning parameters generated by the hearing protection unit.

Embodiments of the present general inventive concept also provide an audio processing device including: an input unit to input media content; and a signal processor to sample digital audio signals decoded from the media content for a predetermined time frame and to sample ambient noise signals obtained through a microphone type input for a predetermined time frame, to calculate mean audio energy and mean noise level accumulated for a predetermined time frame, and to determine whether to perform noise removal based on the calculation.

Embodiments of the present general inventive concept also provide a method of processing audio, including: receiving media content; sampling digital audio signals decoded from the media content for a predetermined time frame and sampling ambient noise signals obtained through a microphone type input for a predetermined time frame; calculating mean audio energy and mean noise level accumulated for a predetermined time frame; and determining whether to perform noise removal based on the calculations.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a block diagram of an audio processing device to provide hearing protection, according to an embodiment of the present general inventive concept;

FIG. 2 is a block diagram showing a signal processor of FIG. 1 in more detail;

FIG. 3 is a block diagram showing a hearing protection unit of FIG. 1 in more detail; and

FIG. 4 is a flowchart of an audio processing method of hearing protection, according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

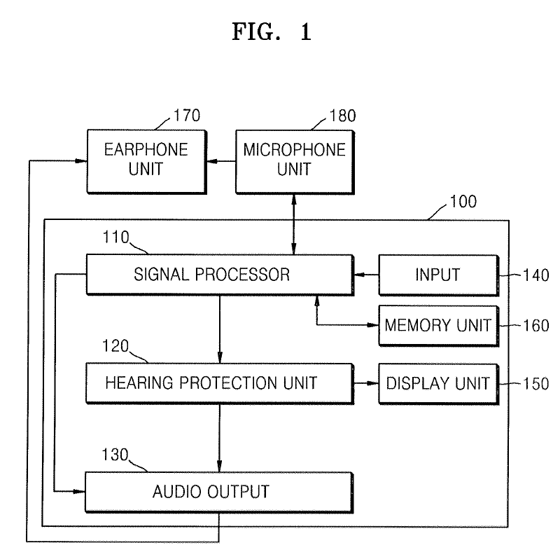

FIG. 1 is a block diagram of an audio processing device to provide hearing protection, according to an embodiment of the present general inventive concept.

The audio processing device of FIG. 1 includes a main body 100, an earphone unit 170, and a microphone unit 180. The main body 100 includes a signal processor 110, a hearing protection unit 120, an audio output 130, an input 140, a display unit 150, and a memory unit 160. Furthermore, although not shown, the audio processing device includes a remote controller connected to the main body 100 by wire and/or wireless.

The input 140 includes a button interface or a touch screen, including a plurality of numeric/alphanumeric input keys and a plurality of function keys, to interface with a user.

The display unit 150 displays various graphics or characters corresponding to warning parameters generated by the hearing protection unit 120.

The memory unit 160 is formed of a read only memory (ROM), a random access memory (RAM), a voice memory, etc., to store a plurality of programs and data, and stores multimedia contents, and various warning parameters to provide hearing protection, etc.

The signal processor 110 samples digital audio signals, which are decoded from media content selected in the input 140, for a predetermined time frame and samples ambient noise signals, which are obtained by the microphone unit 180 attached to the earphone unit 170, for a predetermined time frame. Furthermore, the signal processor 110 calculates the mean audio energy and the mean noise level which is accumulated for a predetermined time frame, determines whether the calculated mean noise level exceeds or is equal to a predetermined critical level, and determines whether to perform noise removal based on the determination result.

The hearing protection unit 120 generates warning parameters for hearing protection each time the mean audio energy exceeds or is equal to a predetermined critical level, outputs the warning parameters to the display unit 150 after converting the warning parameters into various graphics or characters, and adjusts the current audio volume level to a predetermined audio volume level if the mean audio energy exceeds or is equal to the predetermined critical level while a hearing protection mode is enabled by a user. Furthermore, the hearing protection unit 120 also outputs graphics or characters corresponding to warning parameters, as radio frequency (RF) signals, to a liquid crystal display (LCD) panel of the remote controller.

The audio output 130 outputs audio signals, which are converted from digital to analogue signals in the signal processor 110, to the earphone unit 170.

The earphone unit 170 converts the audio signals output from the audio output 130 to sounds and plays the sounds back.

The microphone unit 180 is attached to a predetermined location on the earphone unit 170, and collects and outputs ambient noise signals to the signal processor 110.

The remote controller displays warning parameters that are generated by the hearing protection unit 120 on the LCD panel.

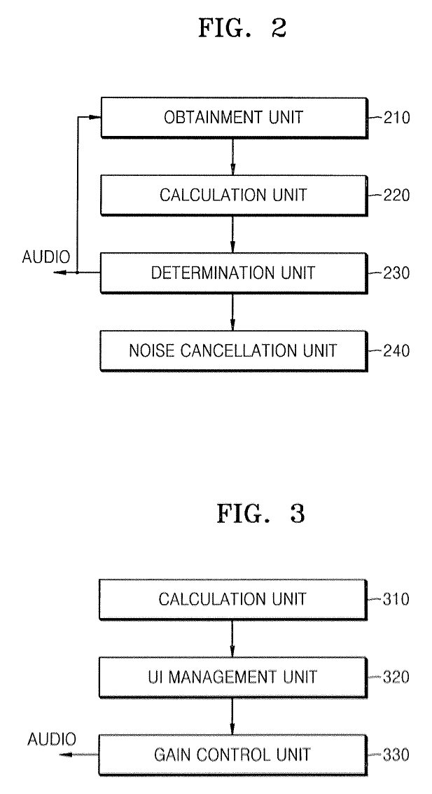

FIG. 2 is a block diagram showing an exemplary embodiment of the signal processor 110 of FIG. 1 in more detail.

The signal processor 110 of FIG. 2 includes an obtainment unit 210, a calculation unit 220, a determination unit 230, and a noise cancellation unit 240.

The obtainment unit 210 obtains multiple audio amplitude values by sampling digital audio signals for a predetermined period of time, obtains multiple noise amplitude values by sampling ambient noise signals for a predetermined period of time, and obtains a current volume level set by a user.

The calculation unit 220 calculates the mean audio energy and the mean noise level for a predetermined period of time based on the multiple audio amplitude values and the multiple noise amplitude values obtained by the obtainment unit 210.

The determination unit 230 determines whether the mean audio energy and the mean noise level that are calculated by the calculation unit 220 exceed or are equal to predetermined critical levels.

The noise cancellation unit 240 performs an active noise cancellation process if the determination unit 230 determines that the mean audio energy and the mean noise level exceed or are equal to the predetermined critical level. At this point, the noise cancellation unit 240 reduces ambient noises included in audio signals by an adaptive filtering.

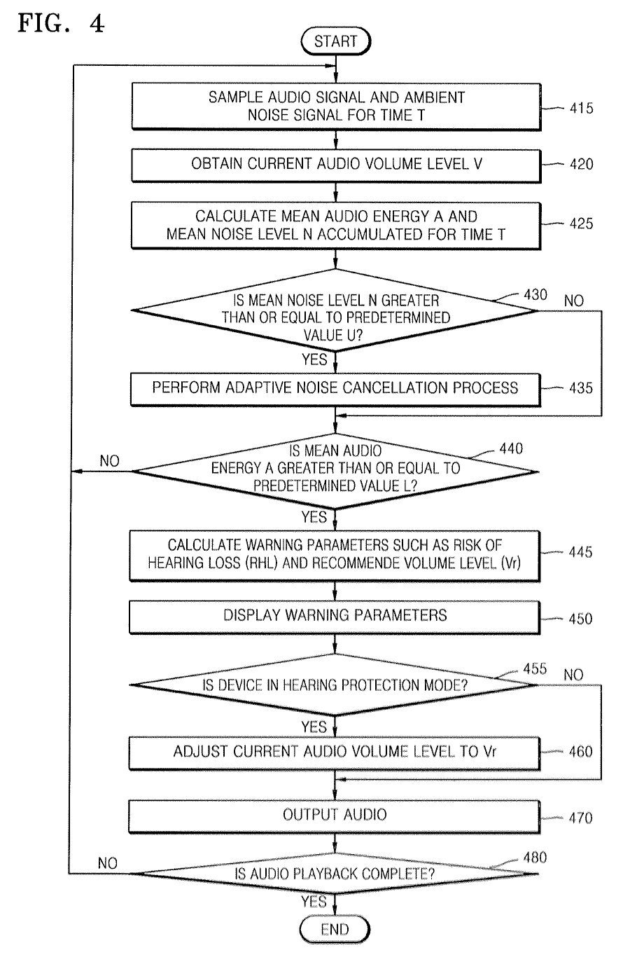

FIG. 3 is a block diagram showing an exemplary embodiment of the hearing protection unit 120 of FIG. 1 in more detail.

The hearing protection unit 120 of FIG. 3 includes a calculation unit 310, a user interface (UI) management unit 320, and a gain control unit 330.

The calculation unit 310 calculates warning parameters such as risk of hearing loss (RHL), recommended volume level (Vr), and recommended audio playback time at the Vr, when the mean audio energy exceeds or is equal to the predetermined critical level.

The UI management unit 320 manages UIs corresponding to warning parameters calculated by the calculation unit 310. Specifically, the UI management unit 320 displays the warning parameters, such as vibrations or text, in their corresponding UIs.

The gain control unit 330 adjusts the current audio volume level to a recommended audio volume level if a hearing protection mode is set in the UIs of the UI management unit 320.

FIG. 4 is a flowchart of an audio processing method of hearing protection, according to an embodiment of the present general inventive concept.

Regarding the method of FIG. 4, first, audio signals and ambient noise signals are sampled for a predetermined time frame T (operation 415). In other words, digital audio signals, which are decoded from media content selected by a user, are sampled for the predetermined time frame T to obtain multiple audio amplitude signals aᵢ.

Furthermore, the ambient noise signals are obtained by using a microphone attached to an earphone or a headphone and an analogue-digital converter. Then, the obtained ambient noise signals are sampled for the predetermined time frame (T) to obtain multiple noise amplitude values nᵢ.

Then, a current audio volume level V set by a user is obtained (operation 420).

Then, a mean audio energy A and a mean noise level N are calculated for the predetermined time frame T, according to algorithms using Mathematical Expressions 1 and 2 defined below (operation 425). At this point, the mean audio energy A and the mean noise level N are root mean square (RMS) values.

$$A = \frac{1}{M} {\sum }_{i = l}^{M} {[ {a}_{i} V ]}^{2} \\ N = {[ \frac{1}{M} {\sum }_{j = l}^{M} {n}_{j}^{2} ]}^{1 / 2} \qquad [ Mathematical Expressions 1 and 2 ]$$

Here, aᵢ represents the amplitude values sampled from digital audio signals for the predetermined time frame T. V represents the current volume level. M represents the number of samples obtained during the predetermined time frame T, and nᵢ represents the amplitude values sampled from digitally converted ambient noises for the predetermined time frame T.

Then, the mean noise level N and a predetermined critical level U are compared with each other (operation 430, where the predetermined critical level U is a reference value for minimizing hearing loss.

If the mean noise level N is greater than the predetermined critical level U, an adaptive noise cancellation process is performed based on the noises input via the microphone attached to the earphone or the headphone (operation 435). At this point, the adaptive noise cancellation process can reduce the pollution of audio signals due to noises to prevent a user from feeling the need to boosting audio volume, and thus help minimize the possibility of hearing loss. According to an embodiment of an adaptive noise cancellation process, noises included in audio signals are estimated by using ambient noises collected by a microphone and original audio signals are recovered from the audio signals including the noises. An adaptive filter, often used for a noise cancellation process, optimizes signals obtained from ambient noises such that the signals are audible by a listener.

Otherwise, if the mean noise level N is smaller than the predetermined critical level U, the adaptive noise cancellation process is skipped.

Then, the mean audio energy A and a predetermined critical level L are compared with each other (operation 440), where the predetermined critical level L is a reference value to minimize hearing loss.

If the mean audio energy A is smaller than the predetermined critical value L (operation 440), the method proceeds back to operation 415 and the following operations, as described above, are repeated for a next predetermined time frame T.

Otherwise, if the mean audio energy A is greater than the predetermined critical value L (operation 440), the warning parameters such as the RHL, the Vr, and the recommended audio playback time at the Vr are calculated (operation 445). The warning parameters are predetermined according to the manufacturer of a portable multimedia device so as to minimize hearing loss. For example, if the volume of audio in playback is maintained in the current audio volume level V, the RHL is a percentage value indicating the likelihood of hearing loss.

Then, the warning parameters are displayed on LCD panels of a portable media device and a remote controller of the portable media device (operation 450).

At this point, the warning parameters are output as specific signals via various UIs such that a user can manually adjust the audio volume level.

Then, it is determined whether a hearing protection mode is enabled (operation 455).

At this point, a user can enable the hearing protection mode by pressing a hearing protection button of a multimedia device using a virtual or physical touch screen.

Then, if the hearing protection mode is enabled, the current audio volume level V is reduced to a recommended audio volume level Vr and displaying of warning parameters is terminated (operation 460).

Therefore, if the hearing protection mode is enabled (operation 455), the current audio volume V is automatically adjusted to a recommended audio volume level to protect the hearing of a user.

Then, digital audio data are converted into analogue audio signals, and the analogue audio signals are output via the earphone or the headphone (operation 470).

Then, it is determined whether audio playback is completed (operation 480).

At this point, if audio playback is completed (operation 480), all the operations are terminated. Otherwise, if audio playback is not completed (operation 480), the method proceeds back to operation 415 and the following operations, as described above, are repeated for a next predetermined time frame T.

In view of the above described exemplary embodiments, the present general inventive concept can effectively protect the hearing of a user by providing either noise cancellation or hearing protection when the user listens to music for an extended period of time with an earphone or a headphone.

The present general inventive concept can also be embodied as computer readable codes on a computer readable recording medium. The computer readable recording medium is any data storage device that can store data, which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An audio processing method comprising:
sampling audio signals and ambient noise signals for a predetermined time frame;
calculating means of audio energy and noise level accumulated for the predetermined time frame, from the sampled audio signals and the sampled ambient noise signals; and
performing a noise cancellation process or a hearing protection process each time the extracted audio energy and the extracted noise level exceed predetermined critical levels.

2. The audio processing method of claim 1, wherein the sampling of the audio signals and the ambient noise signals comprises:
sampling digital audio signals, which are decoded from selected media content, for a predetermined time frame; and
sampling ambient noise signals, which are obtained via a microphone attached to an audio output unit, for a predetermined time frame.

3. The audio processing method of claim 1, wherein the mean audio level (A) and the mean noise level (N) are each calculated by using predetermined algorithms:
$$A = \frac{1}{M} {\sum }_{i = l}^{M} {[ {a}_{i} V ]}^{2}$$
$$N = {[ \frac{1}{M} {\sum }_{j = l}^{M} {n}_{j}^{2} ]}^{1 / 2} ,$$
where aᵢ represents the amplitude values sampled from digital audio signals for the predetermined time frame, V represents a current volume level, M represents the number of samples obtained during the predetermined time frame , and the nᵢ represents amplitude values sampled from digitally converted ambient noises for the predetermined time frame.

4. The audio processing method of claim 1, wherein the performing of the noise cancellation process or the hearing protection process comprises:
performing the noise cancellation process if the mean noise level exceeds a predetermined critical level;
comparing the mean audio energy and a predetermined critical level if the mean noise level does not exceed the predetermined critical level; and
performing the hearing protection process if the mean audio energy exceeds the predetermined critical level.

5. The audio processing method of claim 4, wherein the performing of the noise cancellation process includes performing an adaptive noise cancellation process each time the mean noise level exceeds the predetermined critical level.

6. The audio processing method of claim 4, wherein the performing of the hearing protection process comprises:
calculating warning parameters for hearing protection each time the mean audio energy exceeds the predetermined critical level; and
displaying the warning parameters on display devices.

7. The audio processing method of claim 6, wherein the warning parameters are at least one of a risk of hearing loss, a recommended volume level, and a recommended audio playback time at the recommended volume level.

8. The audio processing method of claim 6, wherein the warning parameters are displayed on a display unit of a multimedia device or on a display unit of a remote controller for the multimedia device.

9. The audio processing method of claim 6, wherein the warning parameters are output as specific signals via various UIs (user interfaces).

10. The audio processing method of claim 4, wherein the performing of the hearing protection process comprises:
determining whether a hearing protection mode is enabled each time the mean audio energy exceeds or is equal to the predetermined critical level; and
adjusting a current audio volume level to a preset recommended volume level if the hearing protection mode is enabled.

11. The audio processing method of claim 10, further comprising:
terminating the displaying of the warning parameters when the current audio volume level is adjusted to the preset recommended audio volume level.

12. An audio processing device comprising:
a signal processor to sample audio signals and ambient noise signals for a predetermined time frame, to calculate means of audio energy and noise level accumulated for the predetermined time frame, and to perform noise removal when the mean noise level exceeds a predetermined critical level;
a hearing protection unit to calculate warning parameters when the mean audio energy exceeds a predetermined critical level and to adjust a current audio volume level to a preset recommended audio volume level if a hearing protection mode is enabled when the mean audio energy exceeds the predetermined critical level; and
a display unit to display warning parameters generated by the hearing protection unit.

13. The audio processing device of claim 12, wherein the display unit is included in a multimedia device or a remote controller for the multimedia device.

14. The audio processing device of claim 12, wherein the signal processor comprises:
an obtainment unit to obtain audio amplitude values by sampling the audio signals for a predetermined time frame and to obtain noise amplitude values by sampling the ambient noise signals for the predetermined time frame;
a calculation unit to calculate the mean audio energy and the mean noise level for the predetermined time frame based on the audio amplitude values and the noise amplitude values obtained by the obtainment unit;
a determination unit to determine whether the mean audio energy and the mean noise level calculated by the calculation unit exceed predetermined critical levels; and
a noise cancellation unit to perform an active noise cancellation process if the determination unit determines that the mean audio energy and the mean noise level exceed the predetermined critical levels.

15. The audio processing device of claim 12, wherein the hearing protection unit comprises:
a calculation unit to calculate warning parameters if the mean audio energy exceeds the predetermined critical level; and
a UI (user interface) management unit to manage UIs corresponding to the warning parameters calculated by the calculation unit and to indicate the warning parameters in their corresponding UIs.

16. The audio processing device of claim 15, wherein the hearing protection unit further comprises a gain control unit to adjust the current audio volume level to a preset audio volume level if the hearing protection mode is enabled.

17. A computer readable recording medium having recorder thereon a program to execute an audio processing method comprising:
sampling audio signals and ambient noise signals for a predetermined time frame;
calculating means of audio energy and noise level accumulated for the predetermined time frame, from the sampled audio signals and the sampled ambient noise signals; and
performing a noise cancellation process or a hearing protection process each time the extracted audio energy and the extracted noise level exceed or are equal to predetermined critical levels.

18. An audio processing device, comprising:
an input unit to input media content; and
a signal processor to sample digital audio signals decoded from the media content for a predetermined time frame and to sample ambient noise signals obtained through a microphone type input for a predetermined time frame, to calculate mean audio energy and mean noise level accumulated for a predetermined time frame, and to determine whether to perform noise removal based on the calculations.

19. The device of claim 18, wherein the determination whether to perform noise removal is based on whether the calculated mean noise level exceeds or is equal to a predetermined critical level.

20. The audio processing device of claim 19, further comprising:
a hearing protection unit to generate warning parameters for hearing protection each time the mean audio energy exceeds or is equal to a predetermined critical level, to output the warning parameters and to adjust the current audio volume level to a predetermined audio volume level when the mean audio energy exceeds or is equal to the predetermined critical level while a hearing protection mode is enabled by a user.

21. The audio processing device of claim 20, wherein the hearing protection unit also outputs graphics or characters corresponding to warning parameters, as radio frequency (RF) signals to an LCD panel of a remote controller.

22. A method of processing audio, comprising:
receiving media content;
sampling digital audio signals decoded from the media content for a predetermined time frame and sampling ambient noise signals obtained through a microphone type input for a predetermined time frame;
calculating mean audio energy and mean noise level accumulated for a predetermined time frame; and
determining whether to perform noise removal based on the calculations.
